(19) United States
(12) Patent Application Publication
(10) Pub. No.: US 2025/0241092 A1
(43) Pub. Date: Jul. 24, 2025

(54) SEMICONDUCTOR LIGHT-EMITTING DEVICES AND METHODS OF MANUFACTURING THE SAME

(71) Applicant: SAMSUNG ELECTRONICS CO., LTD., Suwon-si (KR)

(72) Inventors: Dokyung KIM, Suwon-si (KR); Youngkyu SUNG, Suwon-si (KR); Jonggun WOO, Suwon-si (KR)

(73) Assignee: SAMSUNG ELECTRONICS CO., LTD., Suwon-si (KR)

(21) Appl. No.: 19/020,690

(22) Filed: Jan. 14, 2025

(30) Foreign Application Priority Data
Jan. 19, 2024 (KR) 10-2024-0008932

(51) Int. Cl. H10H 20/831; H10H 20/816; H10H 20/819; H10H 20/833; H10H 29/80

(52) U.S. Cl. CPC H10H 20/8314; H10H 20/8162; H10H 20/819; H10H 20/833; H10H 29/942

(57) ABSTRACT

A semiconductor light-emitting device includes a first light-emitting laminate including a first conductivity type semiconductor layer, an active layer, a second conductivity type semiconductor layer, and a first mesa region in which a boundary is at least partially demarcated by an etched region. The semiconductor light-emitting device further includes a first electrode within the etched region, a first transparent electrode in contact with the second conductivity type semiconductor layer, and a bridge electrode on the first transparent electrode. The first transparent electrode includes a first portion adjacent to the bridge electrode and a second portion further away from the bridge electrode, and the first portion is spaced apart from a first edge of the first mesa region by a first distance, and the second portion is spaced apart from a second edge of the first mesa region by a second distance greater than the first distance.

### CROSS-REFERENCE TO RELATED APPLICATION

This application is based on and claims priority under 35 U.S.C. § 119 to Korean Patent Application No. 10-2024-0008932, filed on Jan. 19, 2024, in the Korean Intellectual Property Office, the disclosure of which is incorporated by reference herein in its entirety.

### BACKGROUND

### 1. Field

Embodiments of the present disclosure relate to a semiconductor light-emitting device, and more particularly, to a semiconductor light-emitting device including a finger electrode portion.

### 2. Brief Description of Background Art

There is an increasing demand for using semiconductor light-emitting devices as light sources of various lighting devices and display devices. For example, a semiconductor light-emitting device includes a p-type semiconductor layer, an n-type semiconductor layer, and an active layer therebetween, and also a p-type electrode electrically connected to the p-type semiconductor layer and an n-type electrode electrically connected to the n-type semiconductor layer. However, the p-type semiconductor layer has relatively high resistivity and thus, current may concentrate on a part adjacent to the p-type electrode. In order to prevent current concentration, a transparent electrode layer is formed on the p-type electrode, but the luminous flux of the semiconductor light-emitting device is lowered by the transparent electrode layer.

### SUMMARY

According to embodiments of the present disclosure, a semiconductor light-emitting device having enhanced luminous flux and simultaneously having excellent electrostatic discharge characteristics is provided.

According to embodiments of the present disclosure, a semiconductor light-emitting device is provided and includes a first cell including a first light-emitting laminate including: a first conductivity type semiconductor layer; an active layer on the first conductivity type semiconductor layer; a second conductivity type semiconductor layer on the active layer; an etched region; and a first mesa region, wherein a boundary of the first mesa region is at least partially demarcated by the etched region. The first cell further includes: a first electrode on the etched region of the first light-emitting laminate and on the first conductivity type semiconductor layer; a first transparent electrode on the first light-emitting laminate and in contact with an upper surface of the second conductivity type semiconductor layer; and a bridge electrode on the first transparent electrode and extending in a first horizontal direction, wherein the first transparent electrode includes a first portion adjacent to the bridge electrode and a second portion that is further than the first portion from the bridge electrode, wherein the first portion of the first transparent electrode is spaced apart from a first edge of the first mesa region, closest to the first portion, by a first distance in a second horizontal direction crossing the first horizontal direction, and wherein the second portion of the first transparent electrode is spaced apart from a second edge of the first mesa region, closest to the second portion, by a second distance greater than the first distance in the second horizontal direction.

According to embodiments of the present disclosure, a semiconductor light-emitting device is provided and includes a first light-emitting laminate including: a first conductivity type semiconductor layer; an active layer on the first conductivity type semiconductor layer; a second conductivity type semiconductor layer on the active layer; an etched region; and a first mesa region, wherein a boundary of the first mesa region is at least partially demarcated by the etched region. The semiconductor light-emitting device further includes a second light-emitting laminate including: a first conductivity type semiconductor layer; an active layer on the first conductivity type semiconductor layer of the second light-emitting laminate; a second conductivity type semiconductor layer on the active layer of the second light-emitting laminate; an etched region; and a second mesa region, wherein a boundary of the second mesa region is at least partially demarcated by the etched region of the second light-emitting laminate. The semiconductor light-emitting device further includes: a first electrode on the etched region of the first light-emitting laminate and on the first conductivity type semiconductor layer; a first transparent electrode on the first light-emitting laminate and in contact with an upper surface of the second conductivity type semiconductor layer of the first light-emitting laminate; a bridge electrode on the first transparent electrode and an upper surface of the first conductivity type semiconductor layer of the second light-emitting laminate, wherein at least a part of the bridge electrode extends in a first horizontal direction; and a second electrode on the second light-emitting laminate and electrically connected to the second conductivity type semiconductor layer of the second light-emitting laminate, wherein the first transparent electrode includes a first portion adjacent to the bridge electrode and a second portion that is further than the first portion from the bridge electrode, wherein the first portion of the first transparent electrode is spaced apart from a first edge of the first mesa region, closest to the first portion, by a first distance in a second horizontal direction crossing the first horizontal direction, and wherein the second portion of the first transparent electrode is spaced apart from a second edge of the first mesa region, closest to the second portion, by a second distance greater than the first distance in the second horizontal direction.

According to embodiments of the present disclosure, a semiconductor light-emitting device is provided and includes a first light-emitting laminate including: a first conductivity type semiconductor layer; an active layer on the first conductivity type semiconductor layer; a second conductivity type semiconductor layer on the active layer; an etched region; a first mesa region, wherein a boundary of the first mesa region is at least partially demarcated by the etched region. The semiconductor light-emitting device further includes a second light-emitting laminate including: a first conductivity type semiconductor layer; an active layer on the first conductivity type semiconductor layer of the second light-emitting laminate; a second conductivity type semiconductor layer on the active layer of the second light-emitting laminate; an etched region; and a second mesa region, wherein a boundary of the second mesa region of the second light-emitting laminate is at least partially demarcated by the etched region of the second light-emitting laminate. The semiconductor light-emitting device further includes: a first electrode on the etched region of the first light-emitting laminate and on the first conductivity type semiconductor layer; a first transparent electrode on the first light-emitting laminate and in contact with an upper surface of the second conductivity type semiconductor layer; a bridge electrode on the first transparent electrode and an upper surface of the first conductivity type semiconductor layer of the second light-emitting laminate, wherein at least a part of the bridge electrode extends in a first horizontal direction; a current blocking layer between the first transparent electrode and the second conductivity type semiconductor layer, wherein the bridge electrode vertically overlaps the bridge electrode; a second transparent electrode on the second light-emitting laminate and in contact with an upper surface of the second conductivity type semiconductor layer of the second light-emitting laminate; and a second electrode on the second transparent electrode, wherein the first transparent electrode includes a first portion adjacent to the bridge electrode and a second portion that is farther than the first portion from the bridge electrode, wherein the first portion of the first transparent electrode is spaced apart from a first edge of the first mesa region, closest to the first portion, by a first distance in a second horizontal direction crossing the first horizontal direction, and wherein the second portion of the first transparent electrode is spaced apart from a second edge of the first mesa region, closest to the second portion, by a second distance greater than the first distance in the second horizontal direction.

### BRIEF DESCRIPTION OF THE DRAWINGS

Embodiments will be more clearly understood from the following detailed description taken in conjunction with the accompanying drawings in which:

FIG. 1 is a top view of a semiconductor light-emitting device according to some embodiments;

FIG. 2 is a cross-sectional view of a portion A1-A1′ of FIG. 1;

FIG. 3 is a cross-sectional view of a portion B1-B1′ of FIG. 1;

FIG. 4 is a cross-sectional view of a portion B2-B2′ of FIG. 1;

FIG. 5 is a layout diagram of a part of a first cell of FIG. 1;

FIG. 6 is an enlarged layout diagram of a part of a second cell of FIG. 1;

FIG. 7 illustrates a layout of a first transparent electrode according to some embodiments;

FIG. 8 illustrates a layout of a first transparent electrode according to some embodiments;

FIG. 9 is a layout diagram of a semiconductor light-emitting device according to some embodiments;

FIG. 10 is a cross-sectional view of the semiconductor light-emitting device taken along a line A2-A2′ of FIG. 9;

FIG. 11 is a cross-sectional view of the semiconductor light-emitting device taken along a line A3-A3′ of FIG. 9;

FIG. 12 is a graph showing a test of the luminous flux of a semiconductor light-emitting device according to comparative examples;

FIG. 13 is a graph showing a static electricity test of a semiconductor light-emitting device according to comparative examples;

FIG. 14 shows an image representing the result of simulation in which static electricity of a semiconductor light-emitting device according to a comparative example is applied;

FIG. 15 is a cross-sectional view of a light source module including a semiconductor light-emitting device according to some embodiments;

FIG. 16 is a perspective view schematically illustrating a lighting device including a semiconductor light-emitting device according to some embodiments;

FIG. 17 is a perspective view schematically illustrating a lighting device including a semiconductor light-emitting device according to some embodiments;

FIG. 18 is a perspective view schematically illustrating a lighting device including a semiconductor light-emitting device according to some embodiments;

FIG. 19 is a perspective view schematically illustrating a lighting device including a semiconductor light-emitting device according to some embodiments;

FIG. 20 is a view schematically illustrating an indoor lighting control network system including a semiconductor light-emitting device according to some embodiments; and

FIG. 21 is a view schematically illustrating a network system including a semiconductor light-emitting device according to some embodiments.

### DETAILED DESCRIPTION

Hereinafter, non-limiting example embodiments of the present disclosure will be described in detail with reference to the accompanying drawings. Throughout the present specification, like reference numerals are used to represent like elements.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

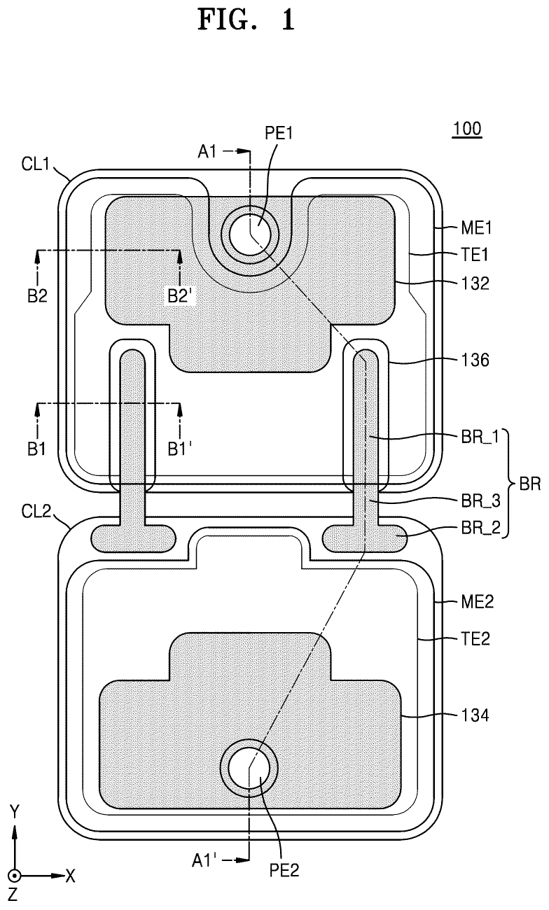

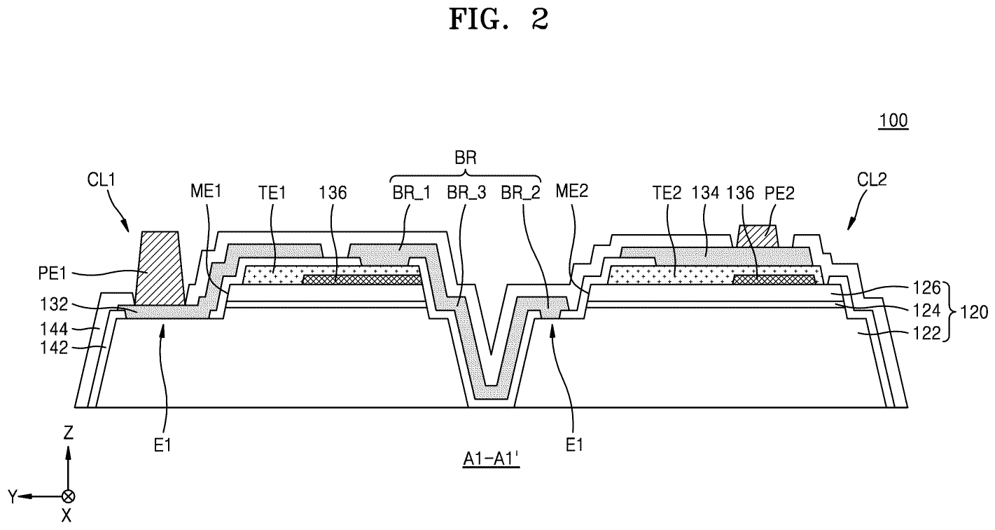

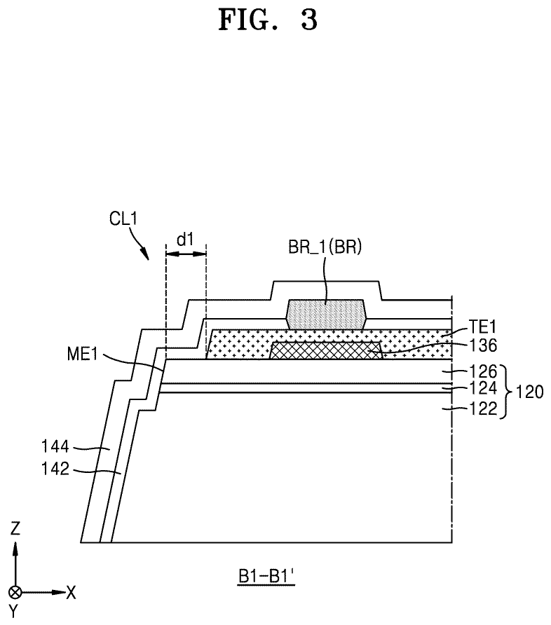

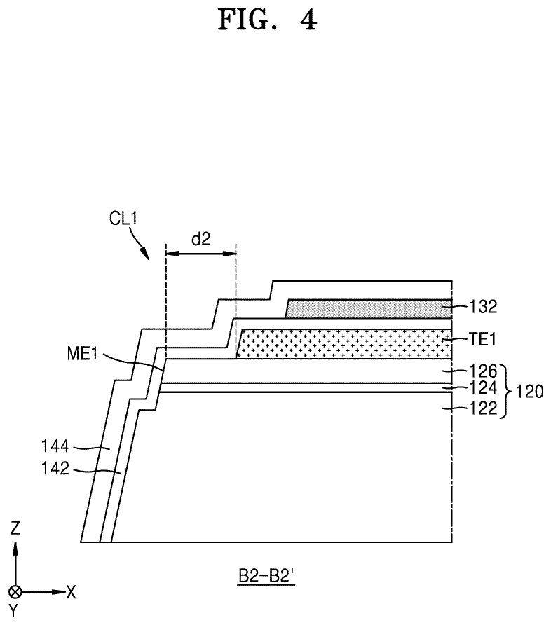

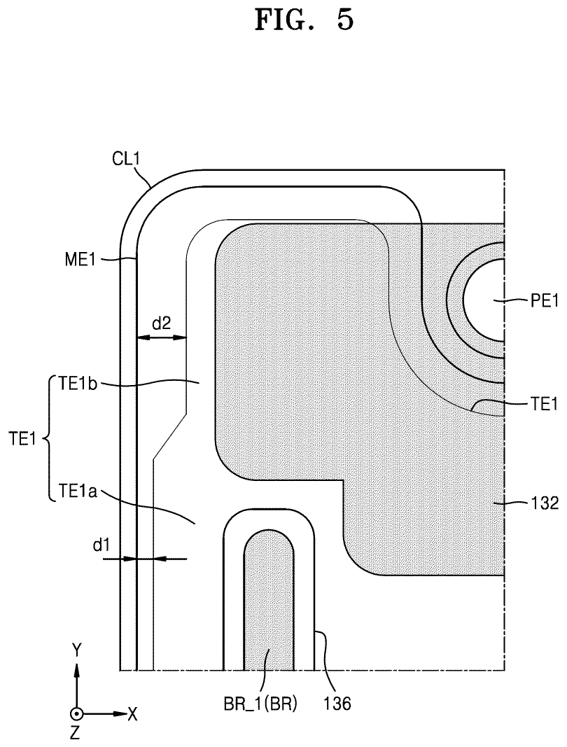

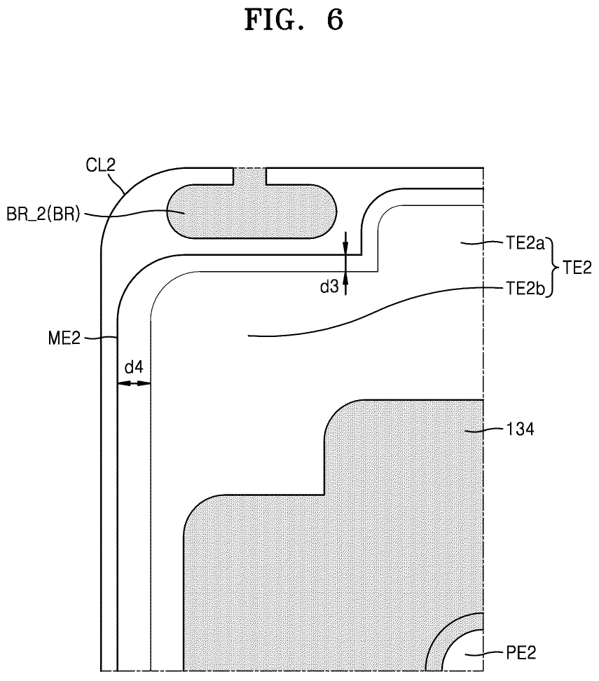

FIG. 1 is a top view of a semiconductor light-emitting device according to some embodiments. FIG. 2 is a cross-sectional view of a portion A1-A1′ of FIG. 1. FIG. 3 is a cross-sectional view of a portion B1-B1′ of FIG. 1. FIG. 4 is a cross-sectional view of a portion B2-B2′ of FIG. 1. FIG. 5 is a layout diagram of a part of a first cell of FIG. 1. FIG. 6 is an enlarged layout diagram of a part of a second cell of FIG. 1.

Referring to FIGS. 1 through 6, a semiconductor light-emitting device 100 may be a multi-junction device in which a first cell CL1 and a second cell CL2 are serially connected to each other. The first cell CL1 and the second cell CL2 may be arranged in parallel and electrically connected to each other by a bridge electrode BR. A first electrode pad PE1 may be disposed on the first cell CL1, a second electrode pad PE2 may be disposed on the second cell CL2, a relatively high voltage may be applied to the first cell CL1 and the second cell CL2 via the first electrode pad PE1 and the second electrode pad PE2, and the first cell CL1 and the second cell CL2 that are serially connected to each other may operate at a relatively high voltage.

Each of the first cell CL1 and the second cell CL2 may include a light-emitting laminate 120. The light-emitting laminate 120 may include a first conductivity type semiconductor layer 122, an active layer 124, and a second conductivity type semiconductor layer 126.

In some embodiments, the first conductivity type semiconductor layer 122 may be a nitride semiconductor having a composition of n-type InₓAl_{y}Ga_{(1-x-y)}N (0≤x<1, 0≤y<1, 0≤x+y<1), and, for example, an n-type impurity may be silicon (Si). For example, the first conductivity type semiconductor layer 122 may include gallium nitride (GaN) in which the n-type impurity is contained.

In some embodiments, the first conductivity type semiconductor layer 122 may include a first conductivity type semiconductor contact layer and a current diffusion layer. The impurity concentration of the first conductivity type semiconductor contact layer may be in a range of 2×10¹⁸ cm⁻³ to 9×10¹⁹ cm⁻³. The thickness of the first conductivity type semiconductor contact layer may be 1 μm to 5 μm. The current diffusion layer may have a structure in which a plurality of InₓAl_{y}Ga_{(1-x-y)}N (0≤x, y≤1, 0≤x+y≤1) layers having different compositions or different impurity contents are alternately stacked. For example, the current diffusion layer may have an n-type superlattice structure in which n-type GaN layers and/or AlₓIn_{y}Ga_{z}N layers (0≤x, y, z≤1, x+y+z≠0) each having a thickness of 1 nm to 500 nm are alternately stacked. The impurity concentration of the current diffusion layer may be 2×10¹⁸ cm⁻³ to 9×10¹⁹ cm⁻³.

The active layer 124 may be disposed between the first conductivity type semiconductor layer 122 and the second conductivity type semiconductor layer 126. The active layer 124 may be configured to emit light having certain energy by recombination of electrons and holes when the semiconductor light-emitting device 100 is driven. The active layer 124 may have a multiple quantum well (MQW) structure in which a quantum well layer and a quantum barrier layer are alternately stacked. For example, the quantum well layer and the quantum barrier layer may have InₓAl_{y}Ga_{(1-x-y)}N (0≤x, y≤1, 0≤x+y≤1) layers having different compositions. For example, the quantum well layer may include InₓGa₁₋ₓN (0≤x≤1), and the quantum barrier layer may be GaN or aluminum gallium nitride (AlGaN). Each of thicknesses of the quantum well layer and the quantum barrier layer may be in a range of 1 nm to 50 nm. The active layer 124 is not limited to having an MQW structure and may have a single quantum well structure.

The second conductivity type semiconductor layer 126 may be a nitride semiconductor layer having a composition of p-type InₓAl_{y}Ga_{(1-x-y)}N (0≤x<1, 0≤y<1, 0≤x+y<1), and, for example, the p-type impurity may be magnesium (Mg).

In some embodiments, the second conductivity type semiconductor layer 126 may include an electron blocking layer stacked in a vertical direction, a low-concentration p-type GaN layer, and a high-concentration p-type GaN layer. For example, the electron blocking layer may have a structure in which a plurality of InₓAl_{y}Ga_{(1-x-y)}N (0≤x, y≤1, 0≤x+y≤1) layers with different compositions each having a thickness of 5 nm to 100 nm are alternately stacked, or may be a single layer including Al_{y}Ga_{(1-y)}N (0<y≤1). An energy band gap of the electron blocking layer may decrease away from the active layer 124. For example, an Al composition of the electron blocking layer may decrease away from the active layer 124.

In some embodiments, the light-emitting laminate 120 may include an etched region E1, and a boundary between a first mesa region ME1 and a second mesa region ME2 may be at least partially demarcated by the etched region E1. For example, the light-emitting laminate 120 of the first cell CL1 may include a first mesa region ME1 and the light-emitting laminate 120 of the second cell CL2 may include a second mesa region ME2.

In some embodiments, as shown in FIG. 1, the planar shape of the first mesa region ME1 may be different from the planar shape of the second mesa region ME2. In some embodiments, the planar shape of the first mesa region ME1 may also be identical to the planar shape of the second mesa region ME2. The etched region E1 may be formed by removing a part of the second conductivity type semiconductor layer 126, the active layer 124, and the first conductivity type semiconductor layer 122. Thus, an upper surface of the first conductivity type semiconductor layer 122 may be exposed at the bottom of the etched region E1.

In some embodiments, the light-emitting laminate 120 may be disposed on a substrate, and, for example, the substrate may include at least one from among sapphire, silicon carbide (SiC), Si, magnesium aluminate (MgAl₂O₄), magnesium oxide (MgO), lithium aluminum dioxide (LiAlO₂), lithium gallium dioxide (LiGaO₂), and GaN. In some embodiments, an uneven portion may also be provided between the substrate and a bottom surface of the light-emitting laminate 120.

The first cell CL1 may include a first transparent electrode TE1 disposed on the upper surface of the second conductivity type semiconductor layer 126 of the first cell CL1, and the second cell CL2 may include a second transparent electrode TE2 disposed on the upper surface of the second conductivity type semiconductor layer 126 of the second cell CL2. In a plan view, the first transparent electrode TE1 may be surrounded by the first mesa region ME1 and the second transparent electrode TE2 may be surrounded by the second mesa region ME2. The layout of the first transparent electrode TE1, the second transparent electrode TE2, the first mesa region ME1, and the second mesa region ME2 is described with reference to FIG. 5 below in detail.

In some embodiments, the first transparent electrode TE1 and the second transparent electrode TE2 may be at least one from among a transparent conductive oxide layer and a transparent conductive nitride layer. For example, the first transparent electrode TE1 and the second transparent electrode TE2 may be at least one selected from a group consisting of indium tin oxide (InSnO), zinc-doped indium tin oxide (ZrInSnO), zinc indium oxide (ZnInO), gallium indium oxide (GaInO), zinc tin oxide (ZnSnO), fluorine-doped tin oxide (SnO), aluminium-doped zinc oxide (ZnO), gallium-doped ZnO, In₄Sn₃O₁₂, and zinc magnesium oxide (Zn₍₁₋ₓ₎MgₓO)(0≤x≤1). In some embodiments, the first transparent electrode TE1 and the second transparent electrode TE2 may include graphene.

The first cell CL1 may include a first electrode 132 connected to an upper surface of the first conductivity type semiconductor layer 122, and the second cell CL2 may include a second electrode 134 electrically connected to the second conductivity type semiconductor layer 126 via the second transparent electrode TE2.

The bridge electrode BR may be electrically connected to the second conductivity type semiconductor layer 126 of the first cell CL1 via the first transparent electrode TE1 and may be electrically connected to the first conductivity type semiconductor layer 122 of the second cell CL2. The bridge electrode BR may have a shape extending to a relatively large length in one direction (e.g., in a second horizontal direction Y) and may also be referred to as a finger electrode.

In some embodiments, the bridge electrode BR may include a first electrode portion BR_1, a second electrode portion BR_2, and a connection portion BR_3. The first electrode portion BR_1 may be disposed on the first transparent electrode TE1 of the first cell CL1 and may be electrically connected to the second conductivity type semiconductor layer 126 of the first cell CL1 via the first transparent electrode TE1. The second electrode portion BR_2 may be disposed in the etched region E1 of the second cell CL2 and disposed on the first conductivity type semiconductor layer 122 of the second cell CL2. The connection portion BR_3 may be disposed on sidewalls of the light-emitting laminate 120 of the first cell CL1 and sidewalls of the light-emitting laminate 120 of the second cell CL2 and may connect the first electrode portion BR_1 and the second electrode portion BR_2 to each other.

In some embodiments, the second conductivity type semiconductor layer 126 of the first cell CL1 may be electrically connected to the first conductivity type semiconductor layer 122 of the second cell CL2 via the bridge electrode BR so that the first cell CL1 and the second cell CL2 may be serially connected to each other. In some embodiments, as shown in FIG. 1, a pair of bridge electrodes BR that connect the first cell CL1 and the second cell CL2 to each other may be disposed, and the pair of bridge electrodes BR may be formed in a mirror symmetrical shape with respect to each other. For example, the first cell CL1 and the second cell CL2 may be disposed adjacent to each other in the second horizontal direction Y, and the pair of bridge electrodes BR may have a mirror symmetrical shape with respect to a central line extending in the second horizontal direction Y. However, in some embodiments, only one bridge electrode BR may be disposed to be connected to the first cell CL1 and the second cell CL2, or three or more bridge electrodes BR may be disposed to be connected to the first cell CL1 and the second cell CL2.

In the first cell CL1, a current blocking layer 136 may be disposed between the first transparent electrode TE1 and the second conductivity type semiconductor layer 126 in a position where the current blocking layer 136 is vertically overlapped by the bridge electrode BR. The current blocking layer 136 may be formed to have a greater width than the width of the bridge electrode BR, and in a plan view, the edge of the current blocking layer 136 may be disposed to surround the bridge electrode BR. The current blocking layer 136 may include an insulating material such as silicon oxide, silicon nitride, aluminum oxide, titanium oxide, or the like.

In some embodiments, the first electrode 132, the second electrode 134, and the bridge electrode BR may include at least one from among silver (Ag), nickel (Ni), Al, chromium (Cr), rhenium (Rh), palladium (Pd), iridium (Ir), ruthenium (Ru), Mg, Zn, platinum (Pt), and gold (Au). At least one from among the first electrode 132, the second electrode 134, and the bridge electrode BR may have a reflective electrode structure. In some embodiments, at least one from among the first electrode 132, the second electrode 134, and the bridge electrode BR may have a double layer structure, such as Ni/Ag, Zn/Ag, Ni/Al, Zn/Al, Pd/Ag, Pd/Al, Ir/Ag, Ir/Au, Pt/Al or Pt/Ag.

An insulating liner 142 may be disposed on sidewalls and an upper surface of the light-emitting laminate 120, and the insulating liner 142 may be configured as electrical insulation between the first electrode 132 and the light-emitting laminate 120, electrical insulation between the second electrode 134 and the light-emitting laminate 120, electrical insulation between the bridge electrode BR and the light-emitting laminate 120, and electrical insulation between the first transparent electrode TE1 and the first electrode 132. The insulating liner 142 may include an insulating material such as silicon oxide, silicon nitride, aluminum oxide, titanium oxide, or silicon oxynitride. In some embodiments, the insulating liner 142 may have a multiple layer structure in which different insulating materials are alternately arranged.

The first electrode 132, the second electrode 134, and the bridge electrode BR may be covered by a passivation layer 144. The passivation layer 144 may include an insulating material such as silicon oxide, silicon nitride, aluminum oxide, titanium oxide, or silicon oxynitride. In some embodiments, the passivation layer 144 may have a multiple layer structure in which different insulating materials are alternately arranged.

The passivation layer 144 may not cover a part of an upper surface of the first electrode 132, and the first pad electrode PE1 may be disposed on the part of the upper surface of the first electrode 132. The passivation layer 144 may not cover a part of an upper surface of the second electrode 134, and a second pad electrode PE2 may be disposed on the part of the upper surface of the second electrode 134. The first pad electrode PE1 and the second pad electrode PE2 may be electrical connection terminals for mounting the semiconductor light-emitting device 100 on a package substrate using a flip chip method.

As shown in FIG. 5, the first transparent electrode TE1 may include a first portion TE1a disposed adjacent to the first electrode portion BR_1 of the bridge electrode BR, and a second portion TE1b disposed not adjacent to (disposed relatively far from) the first electrode portion BR_1 of the bridge electrode BR. For example, the first portion TE1a of the first transparent electrode TE1 may be a portion that overlaps the first electrode portion BR_1 of the bridge electrode BR in a first horizontal direction X, and the second portion TE1b of the first transparent electrode TE1 may be a portion that does not overlap the first electrode portion BR_1 of the bridge electrode BR in the first horizontal direction X.

In some embodiments, in a plan view, the first transparent electrode TE1 may be spaced apart from the first mesa region ME1 and surrounded by the first mesa region ME1. The first portion TE1a of the first transparent electrode TE1 may be spaced apart from the first mesa region ME1 by a first distance d1 in the first horizontal direction X, and the second portion TE1b of the first transparent electrode TE1 may be spaced apart from the first mesa region ME1 by a second distance d2 that is greater than the first distance d1.

Here, the first distance d1 may be a distance between the first portion TE1a of the first transparent electrode TE1 and a point (e.g., a point on an edge of the first mesa region ME1 or a first edge) of the first mesa region ME1 closest to the first portion TE1a in the first horizontal direction X, and the second distance d2 may be a distance between the second portion TE1b of the first transparent electrode TE1 and a point (e.g., a point on an edge of the first mesa region ME1 or a second edge) closest to the second portion TE1b in the first horizontal direction X.

In some embodiments, the first distance d1 between the first portion TE1a of the first transparent electrode TE1 and the first mesa region ME1 may be in a range of 100 nanometers to 10 micrometers. In some embodiments, the second distance d2 between the second portion TE1b of the first transparent electrode TE1 and the first mesa region ME1 may be in a range of 200 nanometers to 20 micrometers.

Sidewalls of the first portion TE1a of the first transparent electrode TE1 may extend in the second horizontal direction Y, and sidewalls of the second portion TE1b of the first transparent electrode TE1 may be offset from the sidewalls of the first portion TE1a in the first horizontal direction X and may extend in the second horizontal direction Y. Accordingly, a connection portion or an inflection point between the first portion TE1a and the second portion TE1b may be disposed at the first transparent electrode TE1, and from this perspective, sidewalls of the first portion TE1a of the first transparent electrode TE1 may protrude outwards from sidewalls of the second portion TE1b of the first transparent electrode TE1.

As the first portion TE1a of the first transparent electrode TE is spaced apart from the first mesa region ME1 by the first distance d1, when current is applied to the first transparent electrode TE1 via the bridge electrode BR (e.g., when the flow of an instantaneous high voltage or a continuous high current such as the occurrence of static electricity is applied to the first transparent electrode TE1 via the bridge electrode BR), current may effectively spread to the first transparent electrode TE1. Thus, the semiconductor light-emitting device 100 may have excellent electrostatic discharge characteristics. Also, as the second portion TE1b of the first transparent electrode TE1 is spaced apart from the first mesa region ME1 by the second distance d2 that is greater than the first distance d1, the second portion TE1b of the first transparent electrode TE1 may have a relatively narrow area, and the light absorption amount may be reduced by the first transparent electrode TE1 so that the luminous flux of the semiconductor light-emitting device 100 may be enhanced.

The second transparent electrode TE2 may be surrounded by the second mesa region ME2 in a plan view. The second transparent electrode TE2 may include a first portion TE2a disposed adjacent to the second electrode portion BR_2 of the bridge electrode BR, and a second portion TE2b disposed far away from the second electrode portion BR_2 of the bridge electrode BR.

The first portion TE2a of the second transparent electrode TE2 may be spaced apart from the second mesa region ME2 by a third distance d3 in the second horizontal direction Y, and the second portion TE2b of the second transparent electrode TE2 may be spaced apart from the second mesa region ME2 by a fourth distance d4 that is greater than the third distance d3.

The third distance d3 may be a distance between the first portion TE2a of the second transparent electrode TE2 and a point (e.g., a point on an edge of the second mesa region ME2 or a first edge) of the second mesa region ME2 closest to the first portion TE2a in the second horizontal direction Y, and the fourth distance d4 may be a distance between the second portion TE2b of the second transparent electrode TE2 and a point (e.g., a point on an edge of the second mesa region ME2 or a second edge) closest to the second portion TE2b in the first horizontal direction X.

In some embodiments, the third distance d3 between the first portion TE2a of the second transparent electrode TE2 and the second mesa region ME2 may be in a range of 100 nanometers to 10 micrometers. In some embodiments, the fourth distance d4 between the second portion TE2b of the second transparent electrode TE2 and the second mesa region ME2 may be in a range of 200 nanometers to 20 micrometers.

As the first portion TE2a of the second transparent electrode TE2 is spaced apart from the second mesa region ME2 by the third distance d3, when current is applied to the second transparent electrode TE2 via the bridge electrode BR (e.g., when the flow of an instantaneous high voltage or a continuous high current such as the occurrence of static electricity is applied to the second transparent electrode TE2 via the bridge electrode BR), current may effectively spread to the second transparent electrode TE2. Thus, the semiconductor light-emitting device 100 may have excellent electrostatic discharge characteristics. Also, as the second portion TE2b of the second transparent electrode TE2 is spaced apart from the second mesa region ME2 by the fourth distance d4 that is greater than the third distance d3, the second portion TE2b of the second transparent electrode TE2 may have a relatively narrow area, and the light absorption amount may be reduced by the second transparent electrode TE2 so that the luminous flux of the semiconductor light-emitting device 100 may be enhanced.

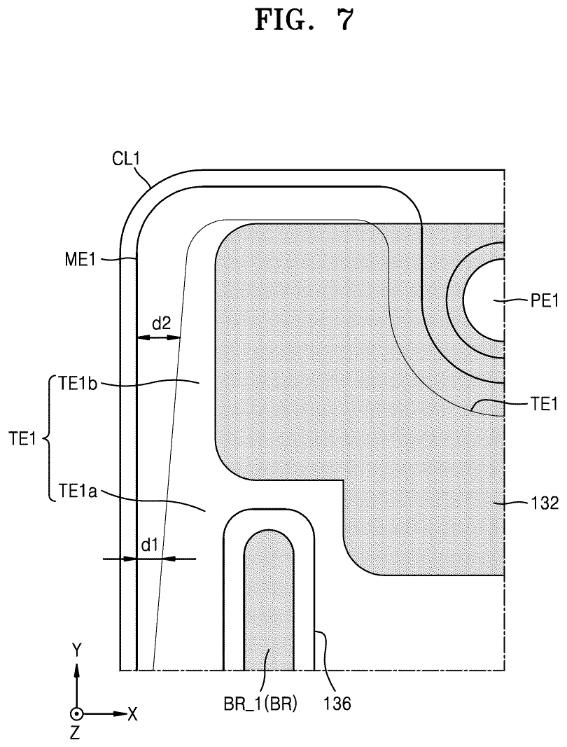

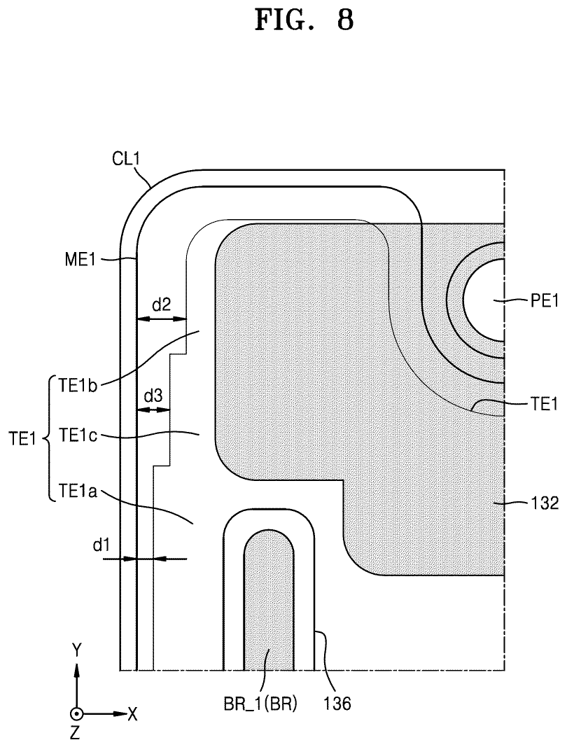

FIGS. 7 and 8 illustrate various layouts of the first transparent electrode TE1 according to some embodiments.

A connection portion is disposed between the first portion TE1a and the second portion TE1b of the first transparent electrode TE1, as described above with reference to FIG. 5, whereas the boundary (e.g., sidewalls of the first transparent electrode TE1) of the first transparent electrode TE1 shown in FIG. 7 may be inclined from the first mesa region ME1.

A connection portion or an inflection point is disposed between the first portion TE1a and the second portion TE1b of the first transparent electrode TE1, as described above with reference to FIG. 5, the first transparent electrode TE1 shown in FIG. 8 may further include a third portion TE1c disposed between the first portion TE1a and the second portion TE1b, and a third distance d3 between the third portion TE1c and the first mesa region ME1 may be greater than the first distance d1 and less than the second distance d2.

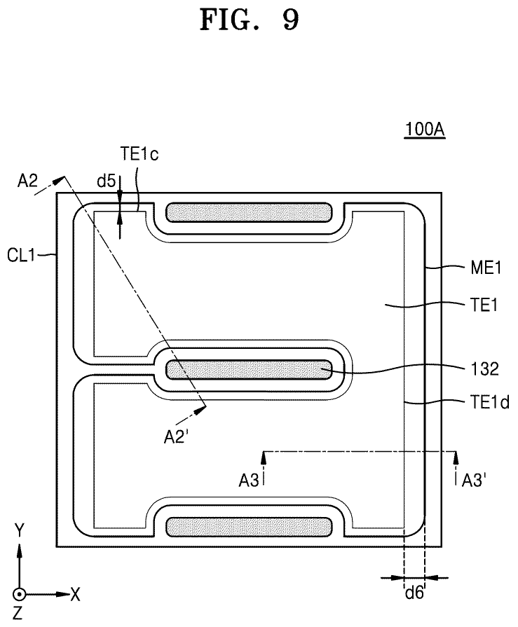

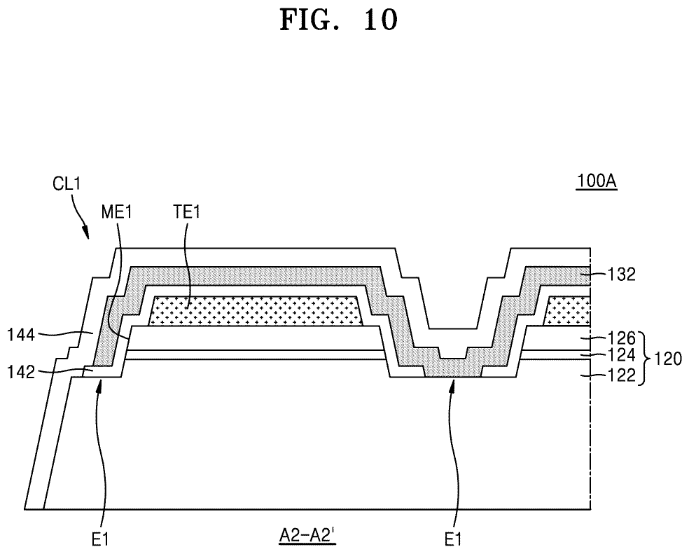

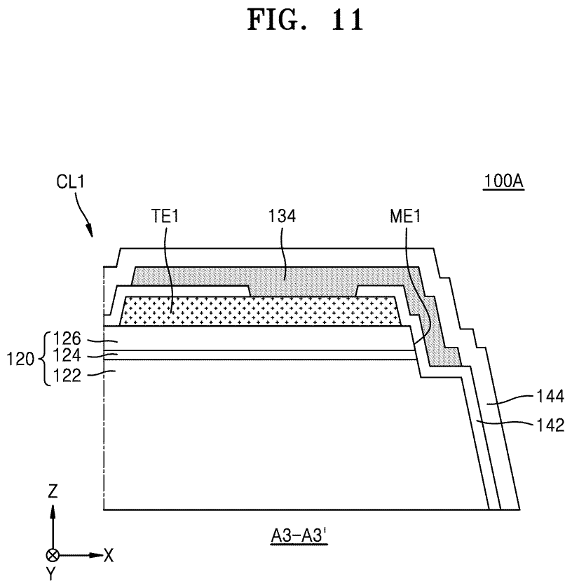

FIG. 9 is a layout diagram of a semiconductor light-emitting device 100A according to some embodiments. FIG. 10 is a cross-sectional view of the semiconductor light-emitting device 100A taken along a line A2-A2′ of FIG. 9, and FIG. 11 is a cross-sectional view of the semiconductor light-emitting device 100A taken along a line A3-A3′ of FIG. 9.

Referring to FIGS. 9 through 11, the semiconductor light-emitting device 100A may be a single junction light-emitting device including only the first cell CL1. For example, the light-emitting laminate 120 may include a first mesa region ME1 demarcated by the etched region E1. The first electrode 132 may extend from the etched region E1 in the second horizontal direction Y, and the first electrode 132 may be a finger-type electrode having a relatively large length.

The first transparent electrode TE1 may include a first portion TE1c disposed adjacent to the first electrode 132, and a second portion TE1d disposed far away from the first electrode 132.

The first portion TE1c of the first transparent electrode TE1 may be spaced apart from the first mesa region ME1 by a fifth distance d5 in the second horizontal direction X, and the second portion TE1d of the first transparent electrode TE1 may be spaced apart from the first mesa region ME1 by a sixth distance d6 that is greater than the fifth distance d5.

The fifth distance d5 may be a distance between the first portion TE1c of the first transparent electrode TE1 and a point (e.g., a point on an edge of the first mesa region ME1 or a first edge) of the first mesa region ME1 closest to the first portion TE1c in the second horizontal direction Y, and the sixth distance d6 may be a distance between the second portion TE1d of the first transparent electrode TE1 and a point (e.g., a point on an edge of the first mesa region ME1 or a second edge) closest to the second portion TE1d in the first horizontal direction X.

In some embodiments, the fifth distance d5 between the first portion TE1c of the first transparent electrode TE1 and the first mesa region ME1 may be in a range of 100 nanometers to 10 micrometers. In some embodiments, the sixth distance d6 between the second portion TE1d of the first transparent electrode TE1 and the first mesa region ME1 may be in a range of 200 nanometers to 20 micrometers.

As the first portion TE1c of the first transparent electrode TE1 is spaced apart from the first mesa region ME1 by the fifth distance d5, when current is applied to the first transparent electrode TE1 via the first electrode 132 (e.g., when the flow of instantaneous high voltage or continuous high current such as the occurrence of static electricity is applied to the first transparent electrode TE1 via the first electrode 132), current may effectively spread to the first transparent electrode TE1. Thus, the semiconductor light-emitting device 100A may have excellent electrostatic discharge characteristics. Also, as the second portion TE1d of the first transparent electrode TE1 is spaced apart from the first mesa region ME1 by the sixth distance d6 that is greater than the fifth distance d5, the second portion TE1d of the first transparent electrode TE1 may have a relatively narrow area, and the light absorption amount may be reduced by the first transparent electrode TEL so that the luminous flux of the semiconductor light-emitting device 100A may be enhanced.

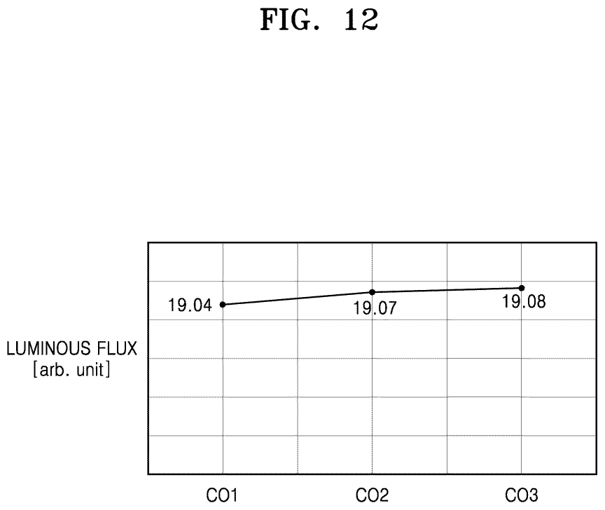

FIG. 12 is a graph showing a test of the luminous flux of a semiconductor light-emitting device according to comparative examples.

In a semiconductor light-emitting device according to a first comparative example CO1, a mesa region and a transparent electrode may be spaced apart from each other by the same first separation distance and, for example, the first separation distance may be 3 micrometers. The same first separation distance means that the entire edge of a transparent electrode is disposed from a mesa region by the same separation distance in a plan view. In a semiconductor light-emitting device according to a second comparative example CO2, a mesa region and a transparent electrode may be spaced apart from each other by the same second separation distance and, for example, the second separation distance may be 5 micrometers. In a semiconductor light-emitting device according to a third comparative example CO3, a mesa region and a transparent electrode may be spaced apart from each other by the same third separation distance and, for example, the third separation distance may be 7 micrometers.

Referring to FIG. 12, as a separation distance between the mesa region and the transparent electrode is increased (e.g., as the transparent electrode is formed with a smaller area), the luminous flux is enhanced. That is, the amount of light absorbed by the transparent electrode may be reduced by a reduction in the area of the transparent electrode so that the luminous flux may be enhanced.

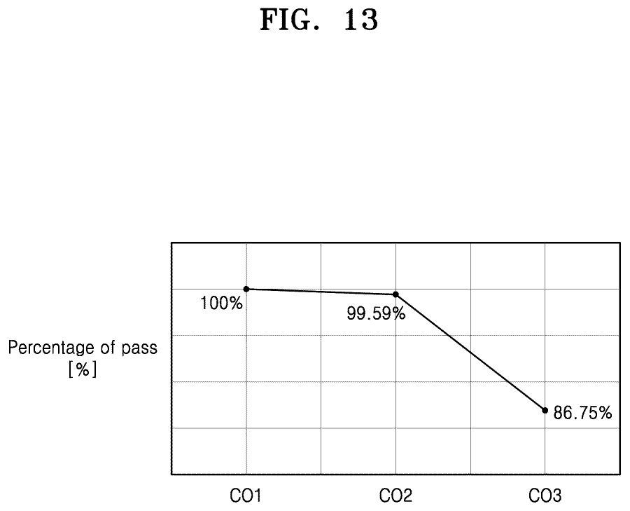

FIG. 13 is a graph showing a static electricity test of a semiconductor light-emitting device according to a comparative example.

In a semiconductor light-emitting device according to a first comparative example CO1, a mesa region and a transparent electrode may be spaced apart from each other by the same first separation distance and, for example, the first separation distance may be 3 micrometers. The same first separation distance means that the entire edge of a transparent electrode is disposed from a mesa region by the same separation distance in a plan view. In a semiconductor light-emitting device according to a second comparative example CO2, a mesa region and a transparent electrode may be spaced apart from each other by the same second separation distance and, for example, the second separation distance may be 5 micrometers. In a semiconductor light-emitting device according to a third comparative example CO3, a mesa region and a transparent electrode may be spaced apart from each other by the same third separation distance and, for example, the third separation distance may be 7 micrometers. 4 kV of static electricity was applied, and the ratio (unit:percentage) of samples that have passed through a static electricity test among all test samples was exhibited.

Referring to FIG. 13, in the first comparative example CO1, all samples have passed through the static electricity test, and in the second comparative example CO2, 99.59% of samples have passed through the static electricity test. On the other hand, in the third comparative example CO3, 86.75% of samples have passed through the static electricity test, resulting in a relatively large failure ratio of 13.25%.

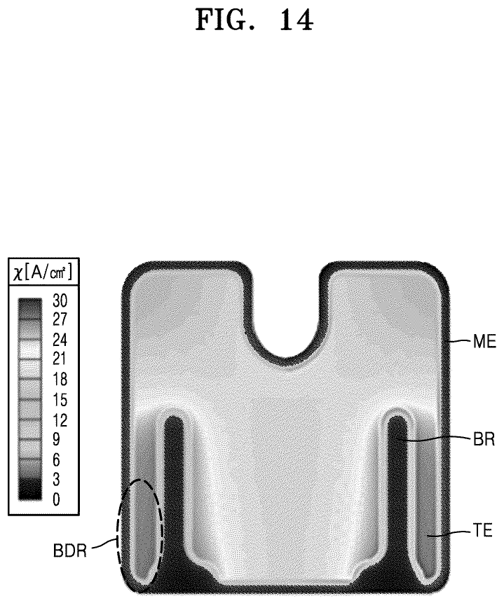

FIG. 14 shows an image representing the result of simulation in which static electricity of a semiconductor light-emitting device according to a comparative example is applied.

Referring to FIG. 14, in a structure in which the mesa region ME surrounds the outside of the transparent electrode TE and the bridge electrode BR is disposed to overlap the transparent electrode TE vertically, current may concentrate on a portion of the transparent electrode TE disposed at both sides of the bridge electrode BR. In FIG. 14, these parts are marked as dashed lines, which may be referred to as a breakdown region BDR. When a separation distance between the mesa region ME and the transparent electrode TE is relatively large, the width of the breakdown region BDR may be reduced, and in this case, cell damage may occur in the breakdown region BDR. For example, as in the third comparative example CO3 of FIG. 13, when the mesa region ME and the transparent electrode TE are spaced apart from each other by a relatively large separation distance, the width of the breakdown region BDR may be reduced. Thus, a locally large current may flow through the narrow breakdown region BDR so that cell damage may occur in the breakdown region BDR.

Referring to FIGS. 12 through 14, when a distance between the mesa region and the transparent electrode is uniform, the luminous flux and electrostatic discharge characteristics are traded off each other. That is, as the distance between the mesa region and the transparent electrode is decreased, the electrostatic discharge characteristics are excellent, whereas, as the distance between the mesa region and the transparent electrode is increased, the luminous flux may be enhanced.

According to some embodiments, a separation distance between the transparent electrode and the mesa region in a region adjacent to the bridge electrode is relatively large, the luminous flux of the semiconductor light-emitting device 100 may be enhanced. Simultaneously, since the separation distance between the transparent electrode and the mesa region is relatively small in a region relatively far away from the bridge electrode, the electrostatic discharge characteristics of the semiconductor light-emitting device 100 may be excellent.

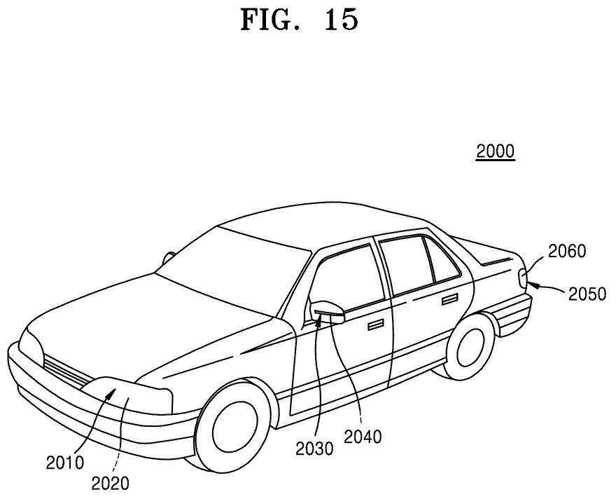

FIG. 15 is a perspective view schematically illustrating a lighting device including a semiconductor light-emitting device according to some embodiments.

Referring to FIG. 15, a head lamp module 2020 may be installed within a head lamp unit 2010 of a vehicle, a side mirror lamp module 2040 may be installed within an external side mirror unit 2030, and a tail lamp module 2060 may be installed within a tail lamp unit 2050. At least one from among the head lamp module 2020, the side mirror lamp module 2040, and the tail lamp module 2060 may be a light source module including at least one from among the semiconductor light-emitting device 100 and the semiconductor light-emitting device 100A described above.

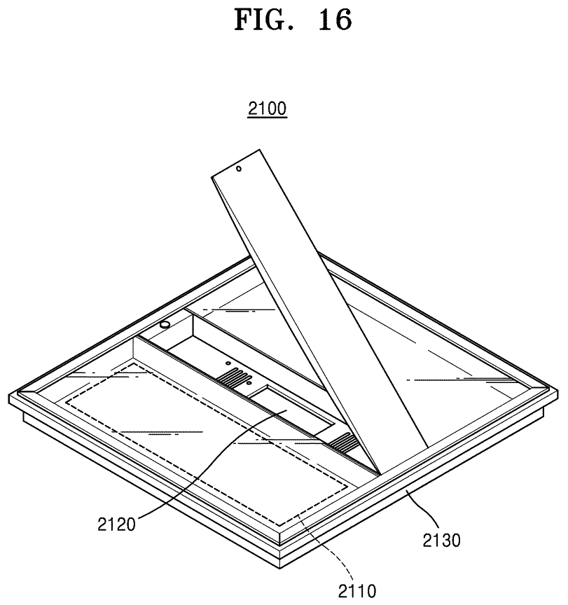

FIG. 16 is a perspective view schematically illustrating a flat lighting device including a semiconductor light-emitting device according to some embodiments.

Referring to FIG. 16, a flat lighting device 2100 may include a light source module 2110, a power supply device 2120, and a housing 2130.

The light source module 2110 may include a light source as a light-emitting device array and may include, as a light source, at least one from among the semiconductor light-emitting device 100 and the semiconductor light-emitting device 100A described above. The light source module 2110 may be formed to have entirely a planar shape.

The power supply device 2120 may be configured to supply power to the light source module 2110. The housing 2130 may have an accommodation space in which the light source module 2110 and the power supply device 2120 are accommodated and may have a hexagonal shape with an opened one side surface of the housing 2130, but embodiments are not limited thereto. The light source module 2110 may be disposed to emit light toward the opened one side surface of the housing 2130.

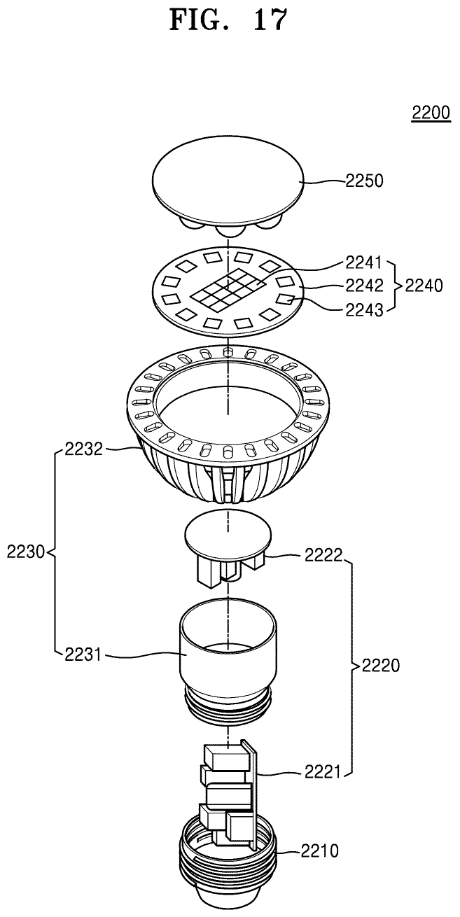

FIG. 17 is an exploded perspective view schematically illustrating a lighting device including a semiconductor light-emitting device according to some embodiments.

Referring to FIG. 17, a lighting device 2200 may include a socket 2210, a power supply unit 2220, a heat dissipation unit 2230, a light source module 2240, and an optical unit 2250.

The socket 2210 may be configured to be replaced with an existing lighting device. Power may be supplied to the lighting device 2200 via the socket 2210. The power supply unit 2220 may be divided into a first power supply unit 2221 and a second power supply unit 2222 and assembled. The heat dissipation unit 2230 may include an internal heat dissipation unit 2231 and an external heat dissipation unit 2232, and the internal heat dissipation unit 2231 may be directly connected to the light source module 2240 and/or the power supply unit 2220. Thus, heat may be transferred to the external heat dissipation unit 2232. The optical unit 2250 may include an internal optical unit and an external optical unit, and may be configured to disperse light emitted by the light source module 2240 uniformly.

The light source module 2240 may emit light toward the optical unit 2250 by receiving power from the power supply unit 2220. The light source module 2240 may include one or more light-emitting device packages 2241, a circuit board 2242, and a controller 2243, and the controller 2243 may store driving information about the light-emitting device package 2241. The light-emitting device package 2241 may include at least one from among the semiconductor light-emitting device 100 and the semiconductor light-emitting device 100A.

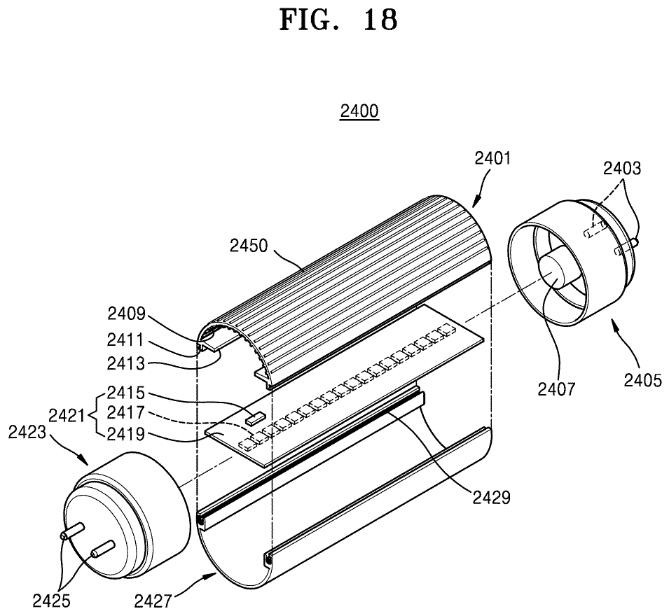

FIG. 18 is an exploded perspective view schematically illustrating a bar-type lighting device including a semiconductor light-emitting device according to some embodiments.

Referring to FIG. 18, a lighting device 2400 may include a heat dissipation member 2401, a cover 2427, a light source module 2421, a first socket 2405, and a second socket 2423. A plurality of heat dissipation fins 2450 and 2409 may be formed to have an unevenness shape on an inner and/or outer surface of the heat dissipation member 2401, and the heat dissipation fins 2450 and 2409 may have various shapes and distances. A support 2413 having a protruding shape may be formed inside the heat dissipation member 2401. The light source module 2421 may be fixed to the support 2413. A hanging jaw 2411 may be formed at both ends of the heat dissipation member 2401.

A hanging groove 2429 may be formed in a cover 2427, and the hanging jaw 2411 of the heat dissipation member 2401 may be coupled into the hanging groove 2429 in a hook coupling structure. A position where the hanging groove 2429 is formed may be changed with a position where the hanging jaw 2411 is formed.

The light source module 2421 may include a printed circuit board 2419, a light source 2417, and a controller 2415. The controller 2415 may store driving information about the light source 2417. Circuit wirings for operating the light source 2417 may be formed on the printed circuit board 2419. Also, components for operating the light source 2417 may be included in the printed circuit board 2419. The light source 2417 may include at least one from among the semiconductor light-emitting device 100 and the semiconductor light-emitting device 100A.

The first socket 2405 and the second socket 2423 may be a pair of sockets and may have a structure in which they are coupled to both ends of a cylindrical cover unit including the heat dissipation member 2401 and the cover 2427. For example, the first socket 2405 may include an electrode terminal 2403 and a power supply device 2407, and a dummy terminal 2425 may be disposed on the second socket 2423. Also, a light sensor and/or a communication module may be embedded in at least one from among the first socket 2405 and the second socket 2423.

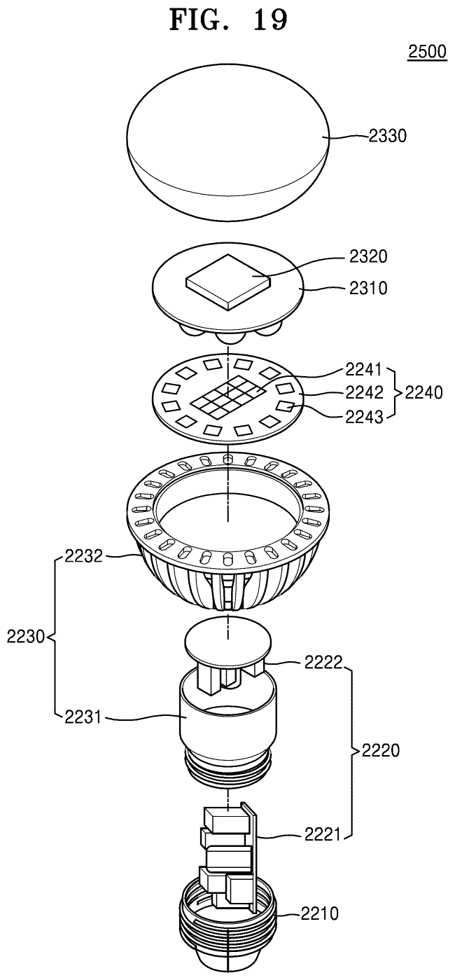

FIG. 19 is an exploded perspective view schematically illustrating a lighting device including a semiconductor light-emitting device according to some embodiments.

Referring to FIG. 19, the difference between a lighting device 2500 according to the present embodiment and the lighting device 2200 described above is that a reflector 2310 and a communication module 2320 are disposed on an upper portion of the light source module 2240. The reflector 2310 may reduce glare by dispersing light from the light source evenly to the side and rear.

The communication module 2320 may be mounted on the reflector 2310, and home-network communication may be implemented by the communication module 2320. For example, the communication module 2320 may be a wireless communication module using Zigbee, wireless fidelity (WiFi) or light fidelity (LiFi), and may control a lighting device installed inside or outside the home such as turning the lighting device on/off, brightness control, or the like via a smartphone or a wireless controller, or may control an electronic product and a vehicle system installed inside or outside the home such as a television (TV), a refrigerator, an air conditioner, a door lock, a vehicle, or the like. The reflector 2310 and the communication module 2320 may be covered by a cover unit 2330.

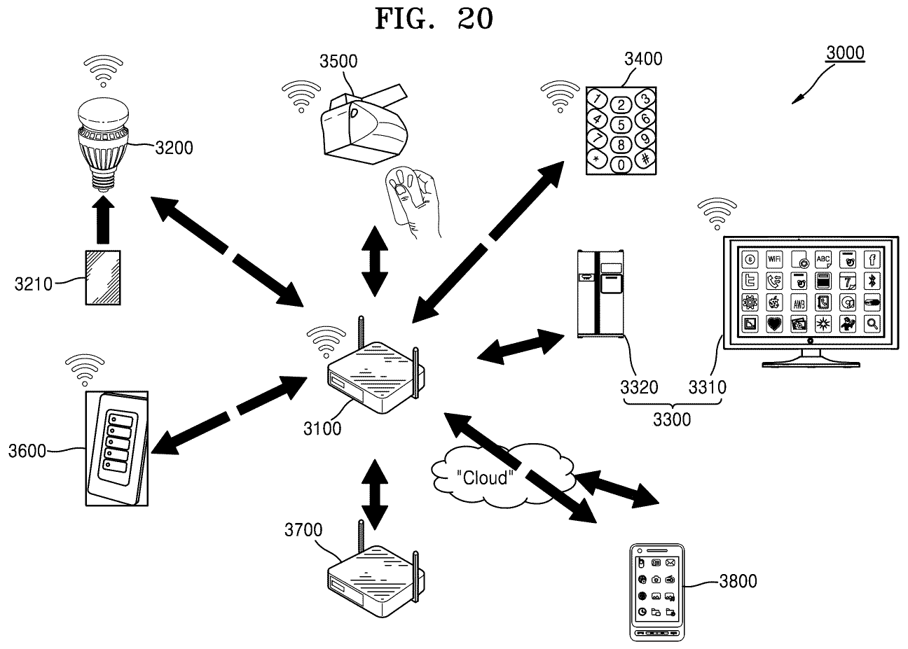

FIG. 20 is a view schematically illustrating an indoor lighting control network system including a semiconductor light-emitting device according to some embodiments.

Referring to FIG. 20, a network system 3000 may be a complex smart lighting-network system in which lighting technology using a light-emitting device such as a light-emitting diode (LED), Internet of Things (IoT) technology, wireless communication technology, and the like are converged. The network system 3000 may be implemented using various lighting devices and wired/wireless communication devices, or may be implemented based on an IoT environment so as to collect/process a variety of information and provide the information to a user.

An LED lamp 3200 included in the network system 3000 may receive information about the ambient environment from a gateway 3100 to control lighting of the LED lamp 3200 itself and may also perform operating state checking and control of other devices included in the IoT environment based on functions such as visible light communication of the LED lamp 3200. The LED lamp 3200 may include at least one from among the semiconductor light-emitting device 100 and the semiconductor light-emitting device 100A described above. The LED lamp 3200 may be connected to the gateway 3100 to communicate with the gateway 3100 by a wireless communication protocol such as WiFi, Zigbee, and LiFi and, to this end, the LED lamp 3200 may have at least one lamp communication module 3210.

If the network system 3000 is applied to the home, the other devices may include a home appliance product 3300, a digital door lock 3400, a garage door lock 3500, a light switch 3600 installed on the wall, a router 3700 for relaying a wireless communication network, and a mobile device 3800 such as a smartphone, a tablet, a laptop computer, or the like.

In the network system 3000, the LED lamp 3200 may check the operating states of the other devices using a wireless communication network (Zigbee, WiFi, LiFi or the like) installed at the home, or may control illuminance of the LED lamp 3200 itself according to ambient environment/situations. Also, the LED lamp 3200 may control the other devices included in the network system 3000 using LiFi communication using visible light emitted from the LED lamp 3200.

First, the LED lamp 3200 may control the illuminance of the LED lamp 3200 automatically based on ambient environment transmitted from the gateway 3100 via the lamp communication module 3210 or ambient environment information collected from a sensor mounted on the LED lamp 3200. For example, the lighting brightness of the LED lamp 3200 may be automatically controlled according to the type of a program broadcasting on a television 3310 or the brightness of a screen. To this end, the LED lamp 3200 may receive operation information about the television 3310 from the lamp communication module 3210 connected to the gateway 3100. The lamp communication module 3210 may be integrally modulated with a sensor and/or a controller included in the LED lamp 3200.

For example, when a digital door lock 3400 is locked when no one is at home and then a predetermined amount of time elapses, all LED lamps 3200 that are turned on may be turned off to prevent electricity consumption. Alternatively, when a security mode is set using the mobile device 3800 or the like, if the digital door lock 3400 is locked when no one is at home, the LED lamp 3200 may be maintained in a turned-on state.

The operation of the LED lamp 3200 may be controlled according to the ambient environment collected using various sensors connected to the network system 3000. For example, when the network system 3000 is implemented within a building, a lighting device, a position sensor and a communication module may be combined with each other in the building and may collect position information about people within the building to turn on or turn off the lighting device or provide collected information in real time so that facility management or efficient utilization of an idle space may be performed.

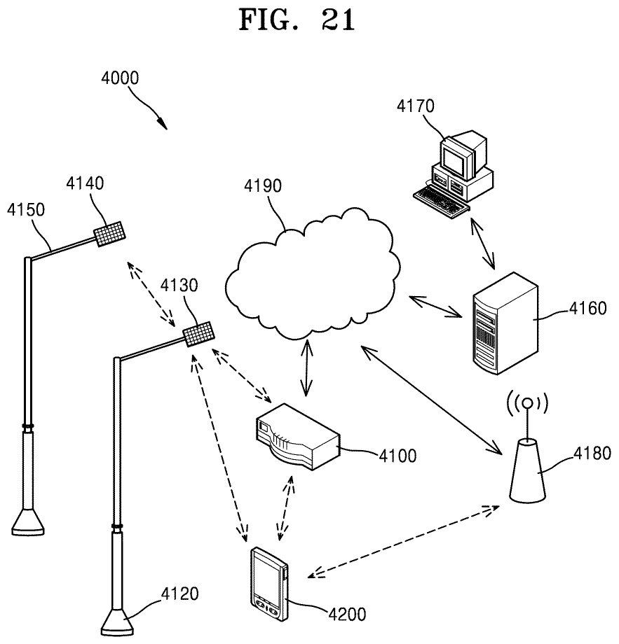

FIG. 21 is a view schematically illustrating a network system including a semiconductor light-emitting device according to some embodiments.

Referring to FIG. 21, a network system 4000 applied to an open space may be provided. The network system 4000 may include a communication connection device 4100, a plurality of lighting instruments (e.g., a first lighting instrument 4120 and a second lighting instrument 4150) installed at certain intervals and connected to communicate with the communication connection device 4100, a server 4160, a computer 4170 for managing the server 4160, a communication base station 4180, a communication network 4190 connecting communication equipment, and a mobile device 4200 (e.g., a mobile communication device).

Each of the plurality of lighting instruments (e.g., the first lighting instrument 4120 and the second lighting instrument 4150) installed in the open outside space such as a street, a park, or the like may include smart engines (e.g., a first smart engine 4130 and a second smart engine 4140). The smart engines may include a light-emitting device for emitting light, a driving driver for driving the light-emitting device, a sensor for collecting information about the ambient environment, and a communication module. The light-emitting device included in the smart engine may include at least one from among the semiconductor light-emitting device 100 and the semiconductor light-emitting device 100A described above.

The smart engines (e.g., the first smart engine 4130 and the second smart engine 4140) may communicate with other peripheral equipment according to a communication protocol such as WiFi, Zigbee, LiFi, or the like using the communication module. One smart engine (e.g., the first smart engine 4130) may be connected to communicate with the other smart engine (e.g., the second smart engine 4140), and WiFi extension technology (e.g., WiFi mesh) may be applied to mutual communication between the smart engines (e.g., the first smart engine 4130 and the second smart engine 4140). At least one smart engine (e.g., the first smart engine 4130) may be connected to the communication connection device 4100 connected to the communication network 4190 via wired/wireless communication with the communication connection device 4100 connected to the communication network 4190.

The communication connection device 4100 may be an access point (AP) through which wired/wireless communication may be performed and may intermediate communication between the communication network 4190 and other equipment. The communication connection device 4100 may be connected to the communication network 4190 using at least one of wired/wireless methods, and for example, may be mechanically accommodated inside of one of the lighting instruments (e.g., the first lighting instrument 4120 and/or the second lighting instrument 4150).

The communication connection device 4100 may be connected to the mobile device 4200 via a communication protocol such as WiFi or the like. A user of the mobile device 4200 may receive ambient environment information collected by the plurality of smart engines (e.g., the first smart engine 4130 and the second smart engine 4140), for example, ambient traffic information, weather information, or the like using the communication connection device 4100 connected to the smart engine (e.g., the first smart engine 4130) of the peripheral lighting instrument (e.g., the first lighting instrument 4120) adjacent to the mobile device 4200. The mobile device 4200 may also be connected to the communication network 4190 using a wireless cellular communication method such as 3rd generation (3G) or 4th generation (4G) via the communication base station 4180.

The server 4160 connected to the communication network 4190 may receive information collected by the smart engines (e.g., the first smart engine 4130 and the second smart engine 4140) mounted on the lighting instruments (e.g., the first lighting instrument 4120 and the second lighting instrument 4150) and simultaneously may monitor the operating states of the lighting instruments (e.g., the first lighting instrument 4120 and the second lighting instrument 4150). The server 4160 may be connected to the computer 4170 that provides a management system, and the computer 4170 may execute software or the like that may monitor and manage the operating states of the smart engines (e.g., the first smart engine 4130 and the second smart engine 4140).

Non-limiting example embodiments have been described above with respect to the drawings. Although the non-limiting example embodiments have been described using specific terms herein, the terms are used as exampled and do not limit the scope of the present disclosure and embodiments thereof. Thus, it will be understood by one of ordinary skill in the art that a variety of modifications and equal examples are included within the scope of the present disclosure, and various changes in form and details may be made therein without departing from the spirit and scope of the present disclosure.

What is claimed is:

1. A semiconductor light-emitting device comprising:
a first cell comprising:
a first light-emitting laminate comprising:
a first conductivity type semiconductor layer;
an active layer on the first conductivity type semiconductor layer;
a second conductivity type semiconductor layer on the active layer;
an etched region; and
a first mesa region, wherein a boundary of the first mesa region is at least partially demarcated by the etched region;
a first electrode on the etched region of the first light-emitting laminate and on the first conductivity type semiconductor layer;
a first transparent electrode on the first light-emitting laminate and in contact with an upper surface of the second conductivity type semiconductor layer; and
a bridge electrode on the first transparent electrode and extending in a first horizontal direction,
wherein the first transparent electrode comprises a first portion adjacent to the bridge electrode and a second portion that is further than the first portion from the bridge electrode,
wherein the first portion of the first transparent electrode is spaced apart from a first edge of the first mesa region, closest to the first portion, by a first distance in a second horizontal direction crossing the first horizontal direction, and
wherein the second portion of the first transparent electrode is spaced apart from a second edge of the first mesa region, closest to the second portion, by a second distance greater than the first distance in the second horizontal direction.

2. The semiconductor light-emitting device of claim 1, wherein the first distance is in a range of 100 nanometers to 10 micrometers, and the second distance is in a range of 200 nanometers to 20 micrometers.

3. The semiconductor light-emitting device of claim 1, wherein the first mesa region surrounds the first transparent electrode in a plan view of the semiconductor light-emitting device.

4. The semiconductor light-emitting device of claim 1, wherein sidewalls of the first portion of the first transparent electrode protrude outwards from sidewalls of the second portion.

5. The semiconductor light-emitting device of claim 1, further comprising a current blocking layer between the first transparent electrode and the second conductivity type semiconductor layer, wherein the bridge electrode vertically overlaps the current blocking layer.

6. The semiconductor light-emitting device of claim 5, wherein a width of the current blocking layer in the second horizontal direction is greater than a width of the bridge electrode in the second horizontal direction.

7. The semiconductor light-emitting device of claim 1, further comprising a second cell on one side of the first cell,
wherein the second cell comprises:
a second light-emitting laminate comprising:
a first conductivity type semiconductor layer,
an active layer on the first conductivity type semiconductor layer of the second light-emitting laminate;
a second conductivity type semiconductor layer on the active layer of the second light-emitting laminate;
an etched region; and
a second mesa region, wherein a boundary of the second mesa region is at least partially demarcated by the etched region of the second light-emitting laminate;
a second transparent electrode on the second light-emitting laminate and in contact with an upper surface of the second conductivity type semiconductor layer of the second light-emitting laminate; and
a second electrode on the second transparent electrode, and
wherein the bridge electrode extends to an upper surface of the first conductivity type semiconductor layer of the second light-emitting laminate.

8. The semiconductor light-emitting device of claim 7, wherein the bridge electrode comprises:
a first electrode portion on an upper surface of the first transparent electrode;
a second electrode portion on the upper surface of the first conductivity type semiconductor layer of the second light-emitting laminate; and
a connection portion on sidewalls of the first light-emitting laminate and sidewalls of the second light-emitting laminate, wherein the connection portion connects the first electrode portion and the second electrode portion to each other.

9. The semiconductor light-emitting device of claim 7, wherein the first cell and the second cell are serially connected to each other.

10. The semiconductor light-emitting device of claim 7, wherein the second transparent electrode comprises:
a first portion adjacent to the bridge electrode; and
a second portion that is further than the first portion of the second transparent electrode from the bridge electrode,
wherein the first portion of the second transparent electrode is spaced apart from a first edge of the second mesa region, closest to the first portion of the second transparent electrode, by a third distance in the first horizontal direction, and
wherein the second portion of the second transparent electrode is spaced apart from a second edge of the second mesa region, closest to the second portion of the second transparent electrode, by a fourth distance greater than the third distance in the second horizontal direction.

11. The semiconductor light-emitting device of claim 10, wherein the third distance is in a range of 100 nanometers to 10 micrometers, and the fourth distance is in a range of 200 nanometers to 20 micrometers.

12. A semiconductor light-emitting device comprising:
a first light-emitting laminate comprising:
a first conductivity type semiconductor layer;
an active layer on the first conductivity type semiconductor layer;
a second conductivity type semiconductor layer on the active layer;
an etched region; and
a first mesa region, wherein a boundary of the first mesa region is at least partially demarcated by the etched region;
a second light-emitting laminate comprising:
a first conductivity type semiconductor layer;
an active layer on the first conductivity type semiconductor layer of the second light-emitting laminate;
a second conductivity type semiconductor layer on the active layer of the second light-emitting laminate;
an etched region; and
a second mesa region, wherein a boundary of the second mesa region is at least partially demarcated by the etched region of the second light-emitting laminate;
a first electrode on the etched region of the first light-emitting laminate and on the first conductivity type semiconductor layer;
a first transparent electrode on the first light-emitting laminate and in contact with an upper surface of the second conductivity type semiconductor layer of the first light-emitting laminate;
a bridge electrode on the first transparent electrode and an upper surface of the first conductivity type semiconductor layer of the second light-emitting laminate, wherein at least a part of the bridge electrode extends in a first horizontal direction; and
a second electrode on the second light-emitting laminate and electrically connected to the second conductivity type semiconductor layer of the second light-emitting laminate,
wherein the first transparent electrode comprises a first portion adjacent to the bridge electrode and a second portion that is further than the first portion from the bridge electrode,
wherein the first portion of the first transparent electrode is spaced apart from a first edge of the first mesa region, closest to the first portion, by a first distance in a second horizontal direction crossing the first horizontal direction, and
wherein the second portion of the first transparent electrode is spaced apart from a second edge of the first mesa region, closest to the second portion, by a second distance greater than the first distance in the second horizontal direction.

13. The semiconductor light-emitting device of claim 12, wherein the first distance is in a range of 100 nanometers to 10 micrometers, and the second distance is in a range of 200 nanometers to 20 micrometers.

14. The semiconductor light-emitting device of claim 12, wherein sidewalls of the first portion of the first transparent electrode protrude outwards from sidewalls of the second portion.

15. The semiconductor light-emitting device of claim 12, further comprising a current blocking layer between the first transparent electrode and the second conductivity type semiconductor layer of the first light-emitting laminate, wherein the bridge electrode vertically overlaps the current blocking layer.

16. The semiconductor light-emitting device of claim 15, wherein a width of the current blocking layer in the second horizontal direction is greater than a width of the bridge electrode in the second horizontal direction.

17. The semiconductor light-emitting device of claim 12, further comprising a second transparent electrode on the second light-emitting laminate and in contact with an upper surface of the second conductivity type semiconductor layer of the second light-emitting laminate, wherein the second electrode is on the second transparent electrode.

18. The semiconductor light-emitting device of claim 17, wherein the first mesa region surrounds the first transparent electrode in a plan view of the semiconductor light-emitting device, and the second mesa region surrounds the second transparent electrode in the plan view.

19. The semiconductor light-emitting device of claim 17, wherein the bridge electrode comprises:
a first electrode portion on an upper surface of the first transparent electrode;
a second electrode portion on the upper surface of the first conductivity type semiconductor layer of the second light-emitting laminate; and
a connection portion on sidewalls of the first light-emitting laminate and sidewalls of the second light-emitting laminate, wherein the connection portion connects the first electrode portion and the second electrode portion to each other.

20. A semiconductor light-emitting device comprising:
a first light-emitting laminate comprising:
a first conductivity type semiconductor layer;
an active layer on the first conductivity type semiconductor layer;
a second conductivity type semiconductor layer on the active layer;
an etched region;
a first mesa region, wherein a boundary of the first mesa region is at least partially demarcated by the etched region;
a second light-emitting laminate comprising:
a first conductivity type semiconductor layer;
an active layer on the first conductivity type semiconductor layer of the second light-emitting laminate;
a second conductivity type semiconductor layer on the active layer of the second light-emitting laminate;
an etched region; and
a second mesa region, wherein a boundary of the second mesa region of the second light-emitting laminate is at least partially demarcated by the etched region of the second light-emitting laminate;
a first electrode on the etched region of the first light-emitting laminate and on the first conductivity type semiconductor layer;
a first transparent electrode on the first light-emitting laminate and in contact with an upper surface of the second conductivity type semiconductor layer;
a bridge electrode on the first transparent electrode and an upper surface of the first conductivity type semiconductor layer of the second light-emitting laminate, wherein at least a part of the bridge electrode extends in a first horizontal direction;
a current blocking layer between the first transparent electrode and the second conductivity type semiconductor layer, wherein the bridge electrode vertically overlaps the current blocking layer;
a second transparent electrode on the second light-emitting laminate and in contact with an upper surface of the second conductivity type semiconductor layer of the second light-emitting laminate; and
a second electrode on the second transparent electrode,
wherein the first transparent electrode comprises a first portion adjacent to the bridge electrode and a second portion that is farther than the first portion from the bridge electrode,
wherein the first portion of the first transparent electrode is spaced apart from a first edge of the first mesa region, closest to the first portion, by a first distance in a second horizontal direction crossing the first horizontal direction, and
wherein the second portion of the first transparent electrode is spaced apart from a second edge of the first mesa region, closest to the second portion, by a second distance greater than the first distance in the second horizontal direction.
